(19) United States
(12) Patent Application Publication
(10) Pub. No.: US 2011/0210734 A1
(43) Pub. Date: Sep. 1, 2011

(54) SYSTEM AND METHOD FOR MR IMAGE SCAN AND ANALYSIS

(76) Inventors: Robert David Darrow, Scotia, NY (US); Thomas Kwok-Fah Foo, Clifton Park, NY (US); Rakesh Mullick, Bangalore (IN); Vivek Prabhakar Vaidya, Bangalore (IN)

(21) Appl. No.: 12/713,924

(22) Filed: Feb. 26, 2010

(51) Int. Cl. G01R 33/48; G06K 9/62

(52) U.S. Cl. 324/309; 382/131

(57) ABSTRACT

A system and method for MR image scan and analysis include an MRI apparatus that includes a magnetic resonance imaging (MRI) system and a computer programmed to automatically prescribe a first scanning protocol based on the selected examination, acquire a first set of MR data of an imaging object via application of the first scanning protocol, and reconstruct a first image from the first set of MR data. The computer is also programmed to automatically prescribe a second scanning protocol based on the first image, acquire a second set of MR data of the imaging object via application of the second scanning protocol, reconstruct a second image from the second set of MR data, and quantify a first parameter of the imaging object based on the second image.

### BACKGROUND OF THE INVENTION

Embodiments of the invention relate generally to magnetic resonance (MR) imaging and, more particularly, to a system and method for MR image scan and analysis.

When a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{Z}, may be rotated, or “tipped”, into the x-y plane to produce a net transverse magnetic moment Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

Conventional MR imaging typically follows a prescribe-ahead imaging model that outputs, for example, images formed of different pixel intensities. In the prescribe-ahead model, a scanning protocol is typically determined based on a desired imaging study, and regardless of the images generated during the scan. The scanning protocol is followed regardless of whether particular scans in the protocol indicate a health issue or are necessary. For example, a particular study of multiple scans may subject a healthy patient to one or more scans designed to locate abnormal tissue even though indicators in a previous image may rule out the existence of such abnormal tissue. In another example, a particular study of multiple scans may subject a patient having abnormal tissue function to one or more scans designed to image normal tissue function even though indicators in a previous image may rule out a diagnostic advantage to acquiring an image of normal tissue function. Additionally, prescribe-ahead imaging may not present images to the user or scanner operator until after all scanning has been completed. Accordingly, the scanner operator may not have an opportunity to eliminate unnecessary scanning. Furthermore, the scanned images may indicate certain conditions or health risks that will only be analyzed at a later date and may require additional scans related to the health risk, requiring additional scans and delaying treatment.

It would therefore be desirable to have a system and method capable of automatically scanning and analyzing images, including diagnosis of the images, during an imaging study to prescribe future imaging scans of diagnostic importance while reducing excess scanning, saving time and improving productivity.

### BRIEF DESCRIPTION OF THE INVENTION

In accordance with an aspect of the invention, an MRI apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images. The MRI apparatus also includes a user interface having at least one selectable examination and a computer programmed to automatically prescribe a first scanning protocol based on the selected examination, acquire a first set of MR data of an imaging object via application of the first scanning protocol, and reconstruct a first image from the first set of MR data. The computer is also programmed to automatically prescribe a second scanning protocol based on the first image, acquire a second set of MR data of the imaging object via application of the second scanning protocol, reconstruct a second image from the second set of MR data, and quantify a first parameter of the imaging object based on the second image.

In accordance with another aspect of the invention, a computer readable storage medium has stored thereon a computer program comprising instructions, which, when executed by a computer, cause the computer to automatically prescribe a first MR pulse sequence based on a user-selected examination study and execute an imaging sequence using the first MR pulse sequence to generate a first image comprising imaging data of an object. The imaging sequence comprises instructions, which when executed by a computer, cause the computer to (A) apply of an MR pulse sequence input into the imaging sequence, (B) acquire of a set of MR data during application of the MR pulse sequence, and (C) reconstruct the set of MR data into an image. The computer is also caused to execute a scan protocol comprising instructions, which when executed by a computer, cause the computer to (D) prescribe a subsequent MR pulse sequence based on one of a previous image and a previous quantification attribute input into the scan protocol, (E) execute the imaging sequence using the subsequent MR pulse sequence to generate a subsequent image comprising imaging data of the object, and (F) generate a subsequent quantification attribute based on the subsequent image. The computer is further caused to display the first quantification attribute to a user.

In accordance with yet another aspect of the invention, an magnetic resonance imaging (MRI) system includes a plurality of RF receiver coils and a computer. The computer has an interface configured to receive an input identifying an examination and is programmed to automatically receive the input identifying the examination, prescribe and execute a localizer MR pulse sequence based on the identified input to acquire localizer imaging data, reconstruct a localizer image from the acquired localizer imaging data, and calculate a scan plane based on the localizer image. The computer is also programmed to automatically prescribe and execute at least one imaging MR pulse sequence based on the scan plane to acquire object imaging data of an object, reconstruct at least one image from the acquired object imaging data, quantify a function of the object based on the reconstructed at least one image, and display the quantified function to a user.

Various other features and advantages will be made apparent from the following detailed description and the drawings.

### BRIEF DESCRIPTION OF THE DRAWINGS

The drawings illustrate preferred embodiments presently contemplated for carrying out the invention.

In the drawings:

FIG. 1 is a schematic block diagram of an MR imaging system incorporating the invention.

FIG. 2 is a flowchart illustrating a technique for automatically scanning and analyzing images according to an embodiment of the invention.

### DETAILED DESCRIPTION

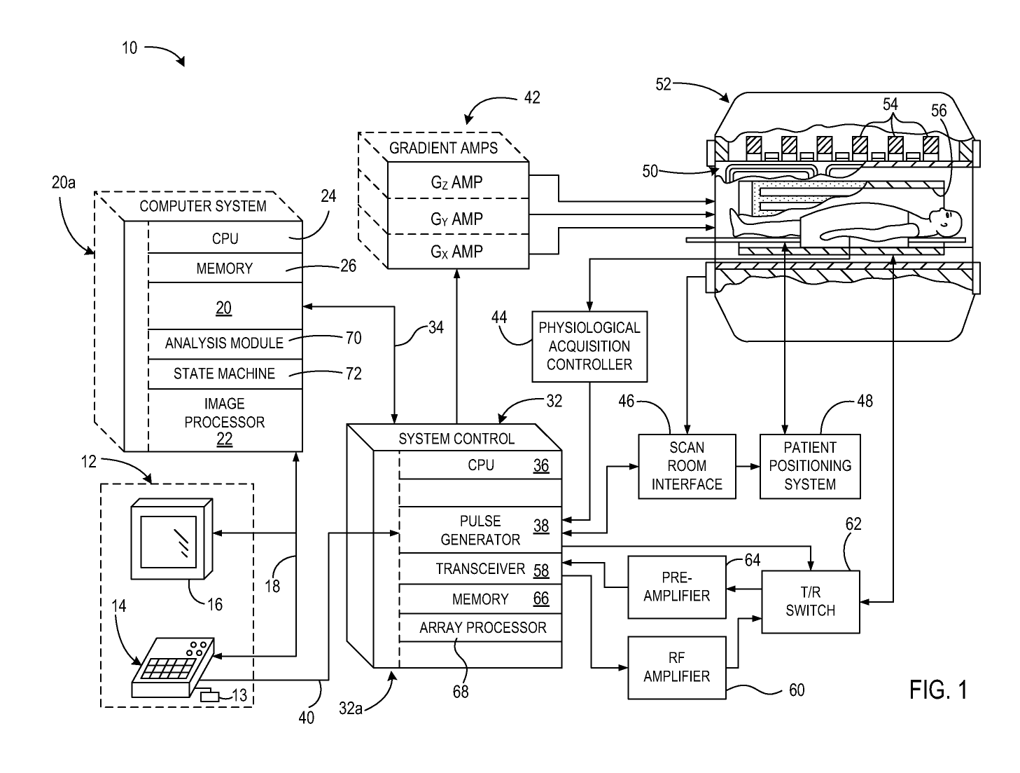

Referring to FIG. 1, the major components of a magnetic resonance imaging (MRI) system 10 incorporating an embodiment of the invention are shown. The operation of the system is controlled for certain functions from an operator console 12, which in this example includes a keyboard or other input device 13, a control panel 14, and a display screen 16. The console 12 communicates through a link 18 with a separate computer system 20 that enables an operator to control the production and display of images on the display screen 16. In one example, the operator has limited interaction with the system as the MRI system 10 includes software routines that automatically perform certain scanning and diagnostic operations. The computer system 20 includes a number of modules which communicate with each other through a backplane 20a. These modules include an image processor module 22, a CPU module 24 and a memory module 26, known in the art as a frame buffer for storing image data arrays. The computer system 20 communicates with a separate system control 32 through a high speed serial link 34. The input device 13 can include a mouse, joystick, keyboard, track ball, touch activated screen, light wand, voice control, card reader, push-button, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. According to one embodiment, the system control 32 also operates according to automated or semi-automated prescription algorithms that provide the information to conduct the scan sequence. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a magnet assembly 52 which includes a polarizing magnet 54 and a whole-body RF coil 56. A transceiver module 58 in the system control 32 produces pulses which are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is subject to post-processing analysis such as contemporaneous automated diagnostic routines and/or stored in memory. In response to commands received from the operator console 12 or as otherwise directed by the system software, this image data may be archived in long term storage or it may be further processed by the image processor 22 and conveyed to the operator console 12 and presented on the display 16 or it may be subject to contemporaneous automated diagnostic routines which may direct further scanning instructions.

According to one embodiment of the invention, computer system 20 also includes an analysis module 70 and a state machine 72. While analysis module 70 and state machine 72 are illustrated as separate components, it is contemplated that a single component may be configured to perform embodiments of the invention as described herein. Analysis module 70 is configured to analyze images processed by the image processor 22 to identify landmarks, calculate scan planes, quantify tissue function, or perform diagnostic analysis as examples. State machine 72, in one embodiment, is configured to keep track of the current imaging state and to transition into a next imaging state, prescribe a revised imaging state or to begin terminating scanning based on an input from analysis module 70 as will be further described below. Transitioning into the next imaging state based on automatically analyzed images includes choosing the next imaging state to further a particular study while eliminating or reducing scans that are not needed or scans that have little diagnostic value. In this manner, scanning time may be reduced, scanner operator involvement may be reduced, and patient throughput may be increased. Transitioning to a revised imaging state based on automatically analyzed images includes choosing a new imaging state to further a study based upon the determination of diagnostic analysis algorithms.

In one embodiment, state machine 72 may be programmed with a decision tree or a decision procedure configured to direct the scanning of a target study along one path or another based on the analysis of a recently analyzed image. Normal tissue functions or differences/anomalies thereof from expected results may lead to different clinical pathways depending on the type of results found. State machine 72, for example, may direct a next scan toward classifying a lesion if the lesion was found in the prior image or may direct the next scan toward quantifying normal tissue function if no lesion was found. Accordingly, state machine 72 may direct scanning in one manner for one patient and in another matter for another patient for the same target study depending on the analyzed images for each patient.

While the MRI system of FIG. 1 illustrates an entire body scan, the systems and methods detailed herein are applicable and configured to subsets of the whole body scanner such that the MRI imaging hardware can be smaller and intended for MR applications and imaging other than an entire body scan. There are a variety of compact and smaller MRI systems such as head only equipment that benefit from the present system.

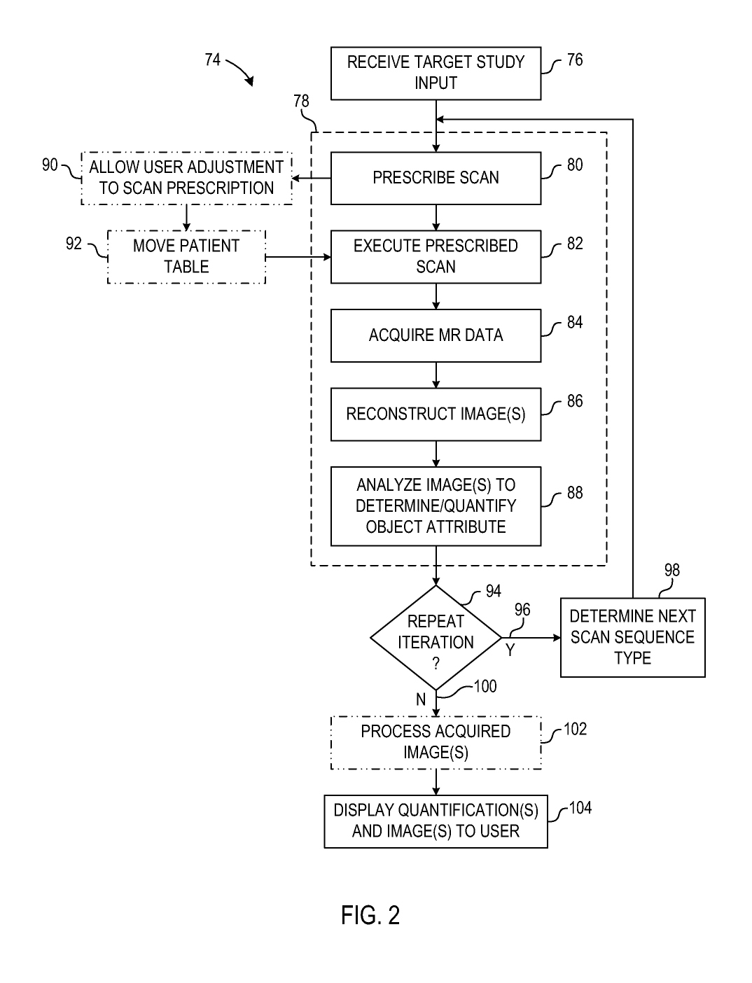

FIG. 2 is a flowchart illustrating a technique 74 for automatically scanning and analyzing images according to an embodiment of the invention. As shown and as will be discussed below, technique 74 includes automated scanning and processing of images by a computer according to a targeted study, for example, to verify or rule out conclusions regarding the existence of normal tissue and function or the existence of abnormal tissue and function and to report quantification of one or more parameters according to the study. Quantification of the parameters as used herein refers to determining or deriving an outcome of the examination, which may include the direct examination results and diagnostic results. Automatic assessment of images and automatic prescription of future imaging scans allows automated decision-making regarding the types of scans and image analyses required to complete the targeted study. The automatic prescription includes initial protocols and/or sequences directed to the desired imaging and, in one example, contains additional diagnostic protocols and/or sequences. An objective of the additional diagnostic protocols and/or sequences is intended to replicate the services performed by a skilled operator. By way of an illustrative example, the initial prescription can be a MR spine examination. Following the localization imaging and automated scan to identify sub-regions, find vertebra and disks and the curvature of the spine, the imaging data is analyzed, and additional diagnostic scanning is performed as part of the automatic scanning to detect lesions and bulging disks. The diagnostic automated scanning helps quantify or identify the size and shape/location of the lesion and any bulging disk would also be identified for geometric deformation or degeneration. In addition, the scan planes are automatically adjusted for each vertebra such that the scan plane is parallel to the planar axes of the vertebra. The further analysis can also include the automatic identification or quantification of the vertebrae (e.g., C1, C2, T1, T2, etc.). According to a further embodiment, the diagnostic protocols and/or sequences includes prognostic protocols and/or sequences intended to anticipate health risks and provide appropriate imaging and diagnostic output that would aid treatment and lower such risks.

Technique 74 includes receiving an user input indicating a desired target study at block 76. In one embodiment, the target study may be directed toward imaging a particular organ or region of the body. For example, the target study may be directed toward cardiac imaging, spinal imaging, neuro/stroke imaging, liver imaging, or breast imaging. Other tissues, organs, and regions are also contemplated herein. The target study input in one embodiment is selectable from a menu in a graphical user interface or otherwise selectable by a user. In another example, the target study input is acquired by an interface configured to read a barcode or a tag, card, or other memory device that may include a priori information as well as prescription and subject data. The operator can be a skilled healthcare professional, although the system accommodates unskilled operators. As the system has multi-purpose imaging capabilities, there are a number of imaging scenarios that can be performed and are selectable by the user. The imaging scenarios each have their own automated scanning routines including image analysis with corresponding automated prescriptions including revised prescriptions and imaging as warranted.

Each target study may begin with an iteration 78 of a series of scanning steps. In one example, the series of scanning steps 78 are designed to localize and/or orient an initial object of interest in the first iteration. Other series of scanning steps include additional scans with diagnostic scanning protocols and parameters using an automated prescription based upon analysis of prior images. In one example, an automated scan uses measurements or other data extracted from prior imaging in order to make a diagnostic scanning protocol. In one aspect, this includes diagnostic analysis for a variety of criteria associated with the analysis and not merely an automated imaging process. One example of such automated analysis is a revised scanning protocol based upon detection such as a tumor, lesion, bulging disk, curved spine, or blood obstructions detected by the image analysis. Another example of automated prescription is a revised scanning protocol with different parameters to enhance an image that is unsatisfactory. There are numerous examples of the revised scanning protocols that imparts intelligence to the imaging analysis.

Iteration 78 includes prescribing a scan at block 80, which prescribes the scan according to the scan type determined for the current iteration 78. For example, to localize or orient the object of interest, a localizer scan may be prescribed. In a non-localizer example, a revised prescription can be performed based on the automated processing and image analysis. At block 82, the prescribed scan is executed. MR data is acquired at block 84, which typically occurs during execution of the prescribed scan. One or more images are reconstructed at block 86 based on the acquired MR data and based on the type of imaging prescribed at block 80.

At block 88, the reconstructed images are analyzed to determine or quantify object attributes according to the scan prescription. For example, for one iteration of blocks 80-88 according to a prescription of a localizer scan, the imaging object may be analyzed at block 88 to determine a scan plane for the next scan iteration. In another example, for one iteration of blocks 80-88 according to a prescription of a non-localizer scan, an attribute or parameter of the imaging object may be quantified at block 88 to determine a function thereof. The function quantified may be, for example, an ejection fraction of the left ventricle of the heart or may be a quantification of the wall motion of the heart or other organ. In one non-localizer embodiment, the imaging object is subject to an automated image diagnostic analysis according to the examination, wherein the initial prescription has initial protocols and sequences and the diagnostic prescription includes diagnostic protocols and sequences.

During each iteration 78, the images may be analyzed multiple times prior to a termination of the iteration 78. For example, the images may first be analyzed to determine if normal wall motion is detected. If normal wall motion is found, the images may be re-analyzed in the same iteration 78 to quantify a parameter or attribute of the normal organ or tissue. If abnormal wall motion is found, the images may be re-analyzed in the same iteration 78 to quantify the abnormal wall motion or to locate a different scan plane for performing another iteration 78 to quantify the abnormal wall motion. In one embodiment each iteration 78 processes the images according to one or more diagnostic protocols and/or sequences in addition to the standard protocol or sequences.

As shown in phantom, technique 74 may include additional steps in iteration 78. Technique 74 may include allowing a user or system operator to view and adjust or modify the scan prescription at block 90. For example, the user may be presented with the prescribed scan slices for verification thereof. Technique 74 may also include moving the patient table 92 to locate the patient in another location. For example, the next scan sequence may be designed to acquire imaging data of a different organ or tissue type located in a different part of the object. In this case, it may be beneficial to move the object so that the different organ or tissue type is ideally positioned within the imaging volume. The movement of the patient table is described in the commonly assigned patent application entitled “Automated Whole Body Moving Table System with Automated Analysis”, U.S. Ser. No. 12/713,745, filed Feb. 26, 2010, and incorporated by reference for all purposes. While FIG. 2 illustrates blocks 90, 92 as being performed after scan prescription at block 80, it is contemplated that blocks 90, 92 may be instead performed at other locations within technique 74.

Following the execution of each iteration 78, technique 74 determines at block 94 whether to repeat another iteration 78 of image acquisition, reconstruction, and analysis. The determination may be based on the current state of the target study as controlled by state machine 72 according to the decision tree or process, for example. As stated above, scanning may be directed in one manner for one patient and in another matter for another patient for the same target study depending on the analyzed images for each patient. Accordingly, the decision tree may determine that more imaging is needed to complete the target study based on the image analysis of the previous iteration 78. In one example, the state machine 72 may cause a first iteration 78 to be performed to acquire and reconstruct a localizer image to determine the scan plane that the next or second iteration 78 should use in order to acquire a diagnostic image for analysis. During the second iteration 78, the reconstructed image(s) may be analyzed to determine whether the object exhibits a normal behavior or function or whether the object exhibits an abnormal behavior or function. If the object exhibits a normal behavior, the reconstructed image(s) may be analyzed to quantify a function of the object. If, however, the object exhibits an abnormal behavior, more iterations 78 may be prescribed and performed to identify, assess, and quantify the abnormal behavior. A revised prescription can also be implemented to image another part of the body or focus on a different area or plane that is derived from the diagnostic analysis.

In another example, repetition of the same iteration may be determined at block 94 to re-acquire imaging data if the quality of the reconstructed image is within a given threshold. For example, given threshold may be a poor image quality based on a coverage of the imaging object in the image, a resolution of the image, artifacts present in the image, or a contrast of the image. Other image quality thresholds are also contemplated herein.

Accordingly, if it is determined that another iteration should be repeated 96, technique 74 determines the next type of scan sequence at block 98. Block 98 thus forms a feedback loop for technique 74. The next scan sequence type may be selected according to the decision tree for the target study. The next scan sequence type is used as an input to the next iteration 78, and process control returns to block 80 to perform another iteration 78 based on the next scan sequence type. The decision tree may include a series of scan iterations 78 to be performed for a particular target study for a normal tissue function of an object. For example, for a cardiac study, the decision tree may include a sequence of iteration events including: 1) acquire localizer images with predetermined localizer scan protocol and determine scan plane prescriptions for short-axis, four-chamber, and two-chamber prescriptions, 2) build a short-axis scan prescription from the computed short-axis scan plane and from a pre-determined short-axis scan protocol to acquire short-axis images, 3) build a four-chamber scan prescription from the computed four-chamber scan plane and from a predetermined four-chamber scan protocol to acquire four-chamber images, 4) build two-chamber scan prescription from the computed two-chamber scan plane and from a predetermined two-chamber scan protocol to acquire two-chamber images, and 5) determine that acquisition is complete.

However, the cardiac study decision tree may acquire additional images targeted to discovering and quantifying an abnormality should such an abnormality be found based on an image analysis performed in any one of the iterations. For example, in a cardiac study to rule out Myocardial Infarction (MI), following a first pass perfusion iteration 78, an iteration 78 may be performed to quantify wall motion of a heart ventricle to determine/identify any areas of abnormality. If no abnormalities are found, another iteration 78 may be performed to quantify a resting perfusion. However, if an abnormality is found, another iteration 78 may be performed according to a Myocardial Delayed Enhancement (MDE) scanning sequence.

If it is determined that iterations are complete 100, at block 102, the images reconstructed or generated during the study may be further processed, for example, to apply artifact reduction or highlighting techniques thereto. Block 102 is shown in phantom and might not be performed by technique 74. Alternatively, it is contemplated that block 102 may be performed at other locations within technique 74 such as after block 88, for example, within each iteration 78. Technique 74 displays quantified parameters and attributes and reconstructed images generated during the execution thereof to the user or system operator at block 104. In another embodiment, the reconstructed images generated during the system operation can be transmitted to a server or communicated to another location for evaluation by a physician. The reconstructed images may also be stored to a disk or memory device, which the patient can take upon completion. The diagnostic protocols and/or sequences can also provide details regarding the analysis and the process that was used to make the measurements as well as diagnostic or prognostic information that would aid in evaluating the results and providing appropriate treatment.

Technique 74 may cause multiple iterations 78 to be performed to determine multiple object features or to quantify multiple object parameters or functions for display to the user. Each iteration 78 is typically based on results from a previous iteration as determined by, for example, analysis module 70 and/or state machine 72. Accordingly, technique 74 allows for a one-touch operation from the user.

Examples of such one-touch scanning will now be described to illustrate possible scanning scenarios performed by technique 74 according to example target studies. These and other examples herein, however, are merely exemplary and do not illustrate the complete scanning and analysis that may be directed by the analysis module 70 and/or state machine 72 programmed to perform the target study.

In an MR spinal exam study example, a localizer scan iteration may be prescribed to identify sub-regions, to find vertebrae and discs, and/or to find a curvature of the spine. Additional scan iterations may be performed based on the results from the localizer scan iteration to detect and quantify a canal width measurement, to detect and measure lesions, and/or to access disks for bulging or degeneration.

In an MR neuro/stroke exam study example, a localizer scan iteration may be prescribed to find symmetry planes in the brain or to identify an anterior commissure (AC) region and a posterior commissure (PC) region of the brain and the relationship between the AC and PC regions. Additional scan iterations may be performed based on the results from the localizer scan iteration to quantify a measure of blood flow and/or blood velocity through obstructed vessels or to quantify a region of infarct.

In an MR liver exam study example, a localizer scan iteration may be prescribed to identify lobes or lobe regions of the liver. Additional scan iterations may be performed based on the results from the localizer scan iteration to quantify a measure of blood flow and/or blood velocity through obstructed vessels or to quantify a region of infarct.

In an MR breast exam study example, a localizer scan iteration may be prescribed to localize and identify scan planes. Additional scan iterations may be performed based on the results from the localizer scan iteration to find potential tumors or lesions, to compute a size as per Response Evaluation Criteria in Solid Tumors (RECIST) criteria, or to register to prior images to provide quantitative comparisons therewith.

In each of these examples, additional scan iterations may be prescribed and performed should other iterations be desired or should abnormal tissues and/or functions be found.

Technique 74 thus allows for a scan-analysis subsystem to automatically prescribe imaging scans and to automatically analyze images to direct future scanning during a target or objective study. The scan-analysis subsystem may perform the imaging and analysis steps to complete the target study without any input from a user or operator after receiving the initial input identifying the target study and/or receiving a user input to begin scanning. Thus, the workflow may be automated, and medical diagnostic exams of increasing sophistication may be performed, where the scanner decides with analysis what additional scanning is needed. Automating the workflow also allows for highly repeatable imaging, elimination of inter- and intra-operator variability, and elimination of the need for a skilled operator to acquire target images.

A technical contribution for the disclosed system and method is that is provides for a computer implemented MR image scan and analysis.

In accordance with an embodiment of the invention, an MRI apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images. The MRI apparatus also includes a user interface having at least one selectable examination and a computer programmed to automatically prescribe a first scanning protocol based on the selected examination, acquire a first set of MR data of an imaging object via application of the first scanning protocol, and reconstruct a first image from the first set of MR data. The computer is also programmed to automatically prescribe a second scanning protocol based on the first image, acquire a second set of MR data of the imaging object via application of the second scanning protocol, reconstruct a second image from the second set of MR data, and quantify a first parameter of the imaging object based on the second image.

In accordance with another embodiment of the invention, a computer readable storage medium has stored thereon a computer program comprising instructions, which, when executed by a computer, cause the computer to automatically prescribe a first MR pulse sequence based on a user-selected examination study and execute an imaging sequence using the first MR pulse sequence to generate a first image comprising imaging data of an object. The imaging sequence comprises instructions, which when executed by a computer, cause the computer to (A) apply of an MR pulse sequence input into the imaging sequence, (B) acquire of a set of MR data during application of the MR pulse sequence, and (C) reconstruct the set of MR data into an image. The computer is also caused to execute a scan protocol comprising instructions, which when executed by a computer, cause the computer to (D) prescribe a subsequent MR pulse sequence based on one of a previous image and a previous quantification attribute input into the scan protocol, (E) execute the imaging sequence using the subsequent MR pulse sequence to generate a subsequent image comprising imaging data of the object, and (F) generate a subsequent quantification attribute based on the subsequent image. The computer is further caused to display the first quantification attribute to a user.

In accordance with yet another embodiment of the invention, an magnetic resonance imaging (MRI) system includes a plurality of RF receiver coils and a computer. The computer has an interface configured to receive an input identifying an examination and is programmed to automatically receive the input identifying the examination, prescribe and execute a localizer MR pulse sequence based on the identified input to acquire localizer imaging data, reconstruct a localizer image from the acquired localizer imaging data, and calculate a scan plane based on the localizer image. The computer is also programmed to automatically prescribe and execute at least one imaging MR pulse sequence based on the scan plane to acquire object imaging data of an object, reconstruct at least one image from the acquired object imaging data, quantify a function of the object based on the reconstructed at least one image, and display the quantified function to a user.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An MRI apparatus comprising:
a magnetic resonance imaging (MRI) system having a plurality of gradient coils positioned about a bore of a magnet, and an RF transceiver system and an RF switch controlled by a pulse module to transmit RF signals to an RF coil assembly to acquire MR images;
a user interface having at least one selectable examination; and
a computer programmed to automatically:
prescribe a first scanning protocol based on the selected examination;
acquire a first set of MR data of an imaging object via application of the first scanning protocol;
reconstruct a first image from the first set of MR data;
prescribe a second scanning protocol based on the first image;
acquire a second set of MR data of the imaging object via application of the second scanning protocol;
reconstruct a second image from the second set of MR data; and
quantify a first parameter of the imaging object based on the second image.

2. The MRI apparatus of claim 1, wherein the selectable examination includes one of the group consisting of spinal examination, vascular examination, functional MR examination, neuro/stroke examination, liver examination, or breast examination.

3. The MRI apparatus of claim 1, wherein the second scanning protocol is a diagnostic protocol.

4. The MRI apparatus of claim 1 wherein the computer is further programmed to automatically prescribe a third scanning protocol based on the first parameter.

5. The MRI apparatus of claim 4 wherein the computer, in being programmed to prescribe the third scanning protocol, is programmed to determine if the first parameter represents one of a normal feature of the imaging object and an abnormal feature of the imaging object.

6. The MRI apparatus of claim 5 wherein the computer, in being programmed to prescribe the third scanning protocol, is programmed to:
automatically prescribe the third scanning protocol according to a first objective if the first parameter represents a normal feature of the imaging object; and
automatically prescribe the third scanning protocol according to a second objective if the first parameter represents an abnormal feature of the imaging object, where the first objective is different from the second objective.

7. The MRI apparatus of claim 6 wherein the computer is further programmed to automatically:
acquire a third set of MR data of the imaging object via application of the third scanning protocol;
reconstruct a third image from the third set of MR data;
quantify a second parameter of the imaging object based on the third image; and
display the second parameter to a user.

8. The MRI apparatus of claim 1 wherein the computer is further programmed to automatically display the first parameter to a user.

9. The MRI apparatus of claim 1 wherein the computer, in being programmed to prescribe the second scanning protocol, is programmed to automatically:
calculate a scan plane based on the first image; and
calculate a scan prescription based on the scan plane.

10. The MRI apparatus of claim 9 wherein the computer, in being programmed to calculate the scan plane, is programmed to automatically calculate one of a cardiac ventricle short axis, a spinal curvature, a relationship of an anterior commissure (AC) region of a brain to a posterior commissure (PC) region of the brain, a lobe region of a liver, and a scan plane of a breast.

11. The MRI apparatus of claim 1 wherein the computer is further programmed to:
determine an image quality of the first or second image; and
repeat the acquisition of the respective first or second set of MR data and the reconstruction of the respective first or second image if the image quality is within a given threshold.

12. The MRI apparatus of claim 11 wherein the given threshold is based on one of a coverage of the imaging object in the first or second image, a resolution of the first or second image, and a contrast of the first or second image.

13. A computer readable storage medium having stored thereon a computer program comprising instructions, which, when executed by a computer, cause the computer to automatically:
prescribe a first MR pulse sequence based on a user-selected examination study;
execute an imaging sequence using the first MR pulse sequence to generate a first image comprising imaging data of an object, wherein the imaging sequence comprises instructions, which when executed by a computer, cause the computer to:
(A) apply of an MR pulse sequence input into the imaging sequence;
(B) acquire of a set of MR data during application of the MR pulse sequence; and
(C) reconstruct the set of MR data into an image;
execute a scan protocol comprising instructions, which when executed by a computer, cause the computer to:
(D) prescribe a subsequent MR pulse sequence based on one of a previous image and a previous quantification attribute input into the scan protocol;
(E) execute the imaging sequence using the subsequent MR pulse sequence to generate a subsequent image comprising imaging data of the object; and
(F) generate a subsequent quantification attribute based on the subsequent image; and
display the first quantification attribute to a user.

14. The computer readable storage medium of claim 13 wherein the instructions further cause the computer to automatically iterate execution of the scan protocol, wherein each execution iteration comprises a distinct MR pulse sequence prescription.

15. The computer readable storage medium of claim 14 the scan protocol further comprises instructions, which, when executed by a computer, cause the computer to automatically:
analyze the one of a previous image and a previous quantification attribute; and
prescribe the subsequent MR pulse sequence in each execution iteration based on the analysis.

16. The computer readable storage medium of claim 14 wherein the instructions further cause the computer to automatically determine, after each execution iteration, if an additional iteration of the scan protocol should be executed.

17. The computer readable storage medium of claim 16 wherein the instructions further cause the computer to automatically halt the iteration of the execution of the scan protocol upon completion of a target study based on the object.

18. The computer readable storage medium of claim 13 wherein the scan protocol further comprises instructions, which, when executed by a computer, cause the computer to automatically:
(G) translate the object from a first location to a second location prior to execution of the scan protocol.

19. The computer readable storage medium of claim 13 wherein the scan protocol further comprises instructions, which, when executed by a computer, cause the computer to automatically:
(G) adjust the prescription of the subsequent MR pulse sequence based on a user modification to the prescription of the subsequent MR pulse sequence.

20. An magnetic resonance imaging (MRI) system comprising:
a plurality of RF receiver coils; and
a computer having an interface configured to receive an input identifying an examination, wherein the computer is programmed to automatically:
receive the input identifying the examination;
prescribe and execute a localizer MR pulse sequence based on the identified input to acquire localizer imaging data;
reconstruct a localizer image from the acquired localizer imaging data;
calculate a scan plane based on the localizer image;
prescribe and execute at least one imaging MR pulse sequence based on the scan plane to acquire object imaging data of an object;
reconstruct at least one image from the acquired object imaging data;
quantify a function of the object based on the reconstructed at least one image; and
display the quantified function to a user.

21. The MRI system of claim 20 wherein the computer is programmed to automatically receive the input identifying the examination via one of a user interface having at least one selectable examination and an interface configured to read a memory device storing subject data.

22. The MRI system of claim 20 wherein the object is a heart;
wherein the computer, in being programmed to acquire object imaging data of the object, is programmed to automatically acquire a plurality of object imaging datasets, wherein each object imaging dataset corresponds to a portion of a cardiac cycle of the heart;
wherein the computer, in being programmed to reconstruct the at least one image, is programmed to automatically reconstruct a plurality of cardiac images from the acquired plurality of object imaging datasets; and
wherein the computer, in being programmed to quantify the function of the object, is programmed to automatically quantify one of an ejection fraction of a ventricle of the heart and a wall motion of a wall of the heart.

23. The MRI system of claim 20 wherein the computer is further programmed to guide the prescription and execution of another MR pulse sequence based on the quantified function.
